(19) United States
(12) Patent Application Publication
(10) Pub. No.: US 2017/0179875 A1
(43) Pub. Date: Jun. 22, 2017

(54) BEAM SPLITTING OF SOLAR LIGHT BY REFLECTIVE FILTERS

(71) Applicant: KING FAHD UNIVERSITY OF PETROLEUM AND MINERALS, Dhahran (SA)

(72) Inventors: Jihad Hassan ALSADAH, Safwa (SA); Nouar Amor TABET, Dhahran (SA)

(73) Assignee: KING FAHD UNIVERSITY OF PETROEUM AND MINERALS, Dhahran (SA)

(21) Appl. No.: 15/446,175

(22) Filed: Mar. 1, 2017

Related U.S. Application Data
(62) Division of application No. 14/324,778, filed on Jul. 7, 2014.

(51) Int. Cl. H02S 40/22; H01L 31/048; H01L 31/052; H01L 31/054; H01L 31/05

(52) U.S. Cl. CPC H02S 40/22; H01L 31/0549; H01L 31/0504; H01L 31/052; H01L 31/0547; H01L 31/048

(57) ABSTRACT

A photovoltaic system is described that improves energy efficiency (conversion of solar energy to electrical energy) by beam-splitting, via reflective filters, the incident solar light into a reflective portion and an exit portion. The reflective portion and the exit portion are directed to respective photovoltaic cells that convert the incident light energy into electrical energy. The concentrated solar light is collimated then split via reflective filters saving on the reflective filter area and reducing overall bulkiness of the beam-splitting system. Further, a cascade of multiple filters is used to split either the reflected spectra or the exit spectra of solar light.

### CROSS REFERENCE TO RELATED APPLICATIONS

This application is a divisional application of U.S. patent application Ser. No. 14/324,788 filed Jul. 7, 2014, the entire contents of each of which are incorporated herein by reference in its entirety.

### BACKGROUND

Field of Disclosure

Embodiments described herein generally relate to improving energy efficiency of a photovoltaic system. Specifically, a photovoltaic system and a method of operation thereof are provided that achieve increased efficiency of the photovoltaic system by beam-splitting solar light with the use of reflective filters, without increasing the bulkiness of the system.

Description of the Related Art

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Solar energy proves to be a good source of natural energy from which electrical energy can be obtained via a photovoltaic system. The photovoltaic system includes a solar cell (also called a photovoltaic cell) that is an electrical device that converts the energy of light (solar energy) directly into electricity by a photovoltaic effect. Photovoltaic systems usually incur a higher cost in energy conversion as compared to energy conversion from other sources. In order to reduce the cost incurred, photovoltaic systems may incorporate solar cells made of inexpensive materials or thin films. To improve the efficiency of photovoltaic systems, multi-junction solar cells (that have efficiency above 40%) could be used. However, multi-junction cells are costly due to the complexity of fabrication and expensive materials used for fabrication. For example, the materials used may include germanium (Ge), gallium indium phosphide (GaInP) and gallium indium arsenide (GaInAs). The success of multi-junction cells is due to utilizing different materials for different parts of the spectrum. In contrast, single junction cells are generally less expensive than multi junction cells. However, they have limited efficiency (10-25%), but designing single junction-cells is simpler and less restrictive in terms of the materials used in fabrication.

An optically concentrated photovoltaic system (CPV) can reduce costs of solar cells by focusing the incoming light on a smaller area of photovoltaic material. Concentration is used to mitigate the high cost of high efficiency multi junction cells. However, the performance of the CPV system is reduced due to overheating the target solar cells. The issue of heat management is particularly more challenging for CPV systems due to the relatively thick multi-junction solar cells as compared to easier cooling for single junction cells.

Multi-junction solar cells are solar cells with multiple p-n junctions made of different semiconductor materials. Each material's p-n junction will produce an electric current in response to a different wavelength of light. A multi junction cell solar cell produces electric current at multiple wavelengths of light, thereby increasing the energy conversion efficiency. However, the construction of such a multi-junction solar cell is complex, as they require proper electric connection (i.e., junctioning) between the multiple junctions and further incur a problem of efficiently cooling the system.

Another approach to convert solar energy into electrical energy in photovoltaic systems is by implementing beam-splitting of the solar light. As shown in FIG. 1A, the photovoltaic system as described by X. Ju et al., in “Numerical analysis and optimization of a spectrum splitting concentration photovoltaic-thermoelectric hybrid system”/Solar Energy 86(2012) 1941-1954, uses a spectral beam splitter (10) that occupies a filter area that is larger than the individual area occupied by the solar cells. Thus, incorporating a large spectral splitter tends to increase the overall photovoltaic system size and cost.

Similarly, as shown in FIG. 1B, the photovoltaic system as described by A. S. Vlasov, et. al., in “Spectral-splitting concentrator photovoltaic modules based on AlGaAs/GaAs/GaSb and GaInP/InGaAs(P) solar cells,” Technical Physics, vol. 58, no. 7, pp. 1034-1038, July 2013, incurs the shortcoming that the solar cells (represented as 101a, 101b and 101c) are positioned further away from one another. Such a configuration of the solar cells also tends to make the overall photovoltaic system design bulky. Further, the area of the reflective filter is still relatively wider than the area of the solar cells

Accordingly an improved photovoltaic system that achieves high efficiency in terms of energy conversion, while keeping the reflective filters areas small, the overall system cost low and the system structure less bulky is disclosed herein.

### SUMMARY

The present disclosure describes a photovoltaic system that incorporates a collimator configured to provide for beam-splitting of the solar light by using reflective filters, after the incident light has been focus at a point or line. The photovoltaic system of the present disclosure improves the energy conversion efficiency, while reducing the overall system cost and bulkiness. Further, the photovoltaic system as described in the present disclosure provides for cascading a plurality of reflective filters arranged in a compact manner and configured to direct the solar energy at a plurality of single-junction photo-voltaic cells.

Accordingly, an aspect of the present disclosure provides a photovoltaic system including a concentrator configured to receive light and focus the received light at a focus line/point of the concentrator; a collimator positioned at the focus point and configured to convert the focused light into a parallel beam of light; a reflective filter positioned at a predetermined distance behind the collimator and disposed at a predetermined angle with respect to the collimator, the reflective filter being configured to receive and split the parallel beam of light into a first portion of light and a second portion of light; a first single-junction photovoltaic cell configured to absorb the first portion of light and convert the absorbed first portion into electrical energy; and a second single-junction photovoltaic cell disposed behind the reflective filter and configured to absorb the second portion of light and convert the absorbed second portion into electrical energy, the second single junction photovoltaic cell being disposed perpendicular to the first single junction photovoltaic cell.

According to another embodiment of the present disclosure is provided a method of photovoltaic energy conversion. The method including: receiving by a concentrator, light from a light source and focusing the received light at, a focus line/point of the concentrator; converting by a collimator positioned at the focus point, the focused light into a parallel beam of light; receiving and splitting by a reflective filter positioned at a predetermined distance behind the collimator and disposed at a predetermined angle with respect to the collimator, the parallel beam of light into a first portion of light and a second portion of light; absorbing by a first single-junction photovoltaic cell the first portion of light and converting the absorbed first portion of light into electrical energy; and absorbing by a second single-junction photovoltaic cell disposed behind the reflective filter, the second portion of light and converting the absorbed second portion of light into electrical energy, the second single junction photovoltaic cell being disposed perpendicular to the first single junction photovoltaic cell.

The foregoing paragraphs have been provided, by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

Various embodiments of this disclosure that are proposed as examples will be described in detail with reference to the following figures, wherein like numerals reference like elements, and wherein:

FIG. 1A and FIG. 1B illustrate configurations of a photovoltaic system that incorporate beam-splitting;

FIG. 2 depicts a configuration of a photovoltaic system according to an embodiment;

FIGS. 3A-3H illustrate different configurations of reflective filter(s) in the photovoltaic system;

FIG. 4 depicts a flowchart illustrating the steps performed by the photovoltaic system; and

FIG. 5 illustrates a block diagram of a computing device according to an embodiment.

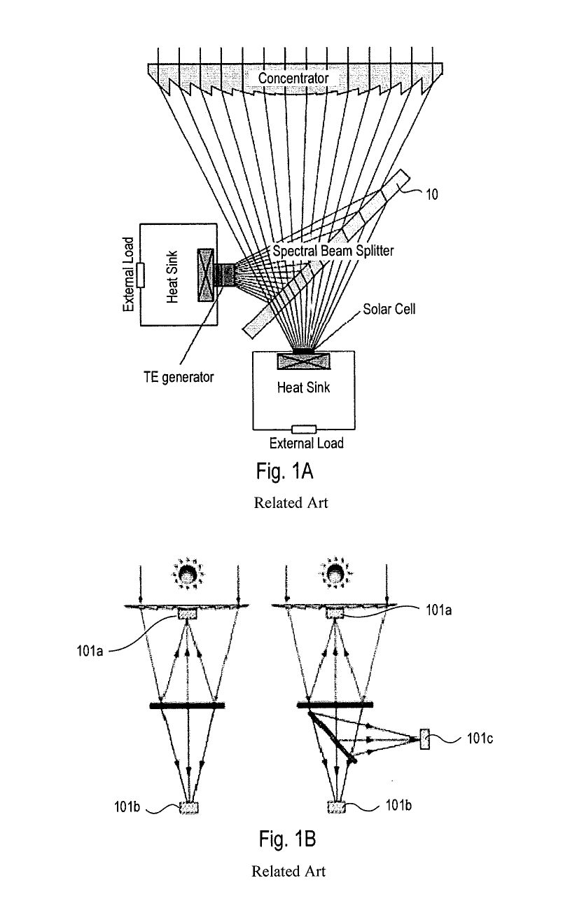

### DETAILED DESCRIPTION OF EMBODIMENTS

In a solid-state semiconductor, a solar cell is made from two doped crystals, one an n-type semiconductor, which has extra free electrons, and the other a p-type semiconductor, which is lacking free electrons. When placed in contact, some of the electrons in the n-type portion will flow into the p-type portion to “fill in” the missing electrons, also known as “holes.” Eventually enough electrons will flow across the boundary to equalize a Fermi level of the two materials. This results in a region being formed at the interface, known as the p-n junction, where charge carriers are depleted and/or accumulated on each side of the interface. For instance, in a silicon based semiconductor, the transfer of electrons produces a potential barrier of about 0.6 V to 0.7 V.

When placed in the sun, photons in the sunlight can strike the bound electrons in the p-type side of the semiconductor, giving them more energy, a process known as “photo-excitation.” In silicon, for instance, sunlight can provide enough energy to push an electron out of the lower-energy valence band into the higher-energy conduction band. The electrons in the conduction band are free to move about the silicon. When a load is placed across the solar cell as a whole, the electrons flow out of the p-type side into the n-type side and lose energy while moving through the external circuit. Eventually, the electrons transition back into the p-type material where they can once again re-combine with the valence-band hole they left behind, producing a lower-energy photon or heat. In such a manner, a photovoltaic cell can convert solar energy (sunlight) to electrical energy (electrical current).

Solar energy is multi-spectral light at about 1361 Watt/m² just outside the atmosphere of the Earth. The solar energy spectrum corresponds to a black body radiation of about 5800 K⁰. As this light passes through the atmosphere, gases in the atmosphere absorb part of the spectrum. The amount of light energy reaching the surface of earth depends on the geographic location, season and time of the day. A standard value of 1000 W/m² (Air Mass 1.5) is used for testing flat photovoltaic panels.

Furthermore, a physical limit governing the theoretical efficiency of a solar panel that uses a p-n junction to collect power from the cell is defined by the Shockley-Queisser limit or detailed balance limit. The limit places maximum solar conversion efficiency around 33.7% assuming a single p-n junction with a band gap of 1.34 electron-volts. That is, of all the power contained in sunlight falling on an ideal solar cell (about 1000 W/m²), only 33.7% of that could ever be turned into electricity (337 W/m²). The losses are largely due to practical concerns like reflection off the front surface and light blockage from the thin wires on its surface.

Note that the Shockley-Queisser limit only applies to cells with a single p-n junction. Cells with multiple layers can outperform this limit. In fact, one technique is to stack layers of different materials on top of each other (multi-junction) so that each layer absorbs part of the spectrum. This technology has allowed the fabrication of solar cells of power conversion efficiency exceeding the thermodynamic limit. However, layering and junctioning the solar cell is a complex process which results in high cost of the system.

In what follows, a configuration of a photovoltaic system that uses single junction photovoltaic cells is described, The system provides for beam splitting of the solar light by reflective mirrors that are arranged in a compact fashion. Further, a method performed by the photovoltaic system to convert solar energy into electrical energy is also described.

The photovoltaic system achieves improved absorption of solar light by using single junction photovoltaic cells of different band gap energies. Thus, in contrast to multi-junction photovoltaic cells, the single junction cells are easier to fabricate and also avoid the problem of current matching that is usually faced by the multi-junction photovoltaic cells. Further, the single junction photovoltaic cells provide for efficient cooling mechanisms (i.e., back side cooling of the photovoltaic cells) which is difficult to achieve in multi-junction photovoltaic cells that are stacked vertically on top of each other.

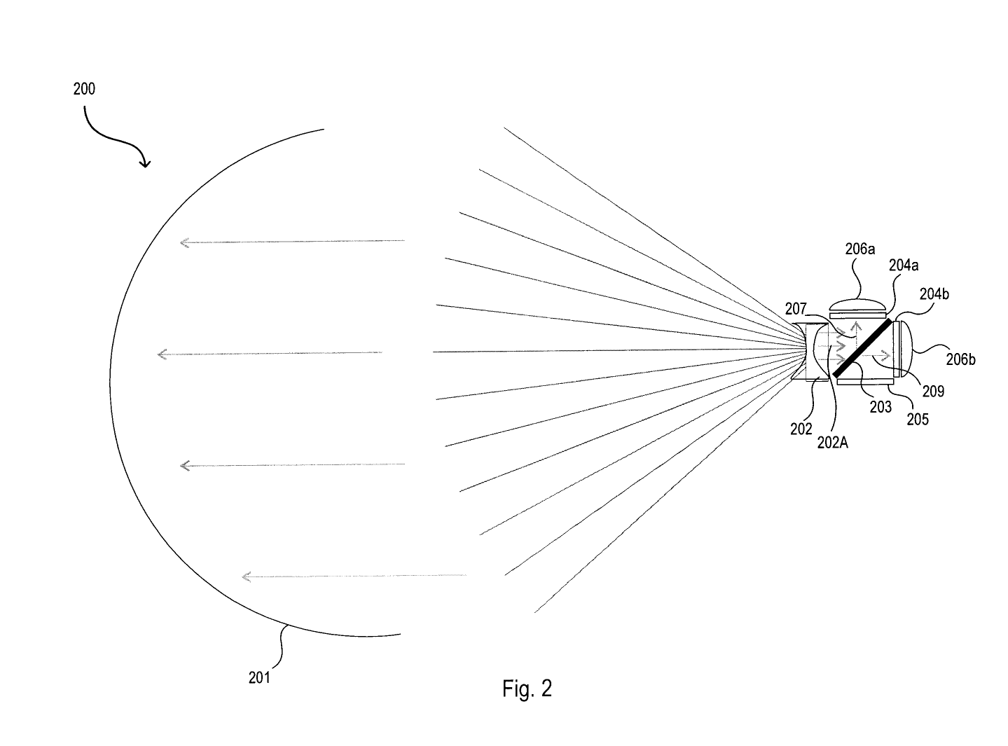

FIG. 2 illustrates a configuration of a photovoltaic system 200 according to an embodiment of the present disclosure.

The configuration 200 includes a parabolic trough 201 configured to capture solar light that is incident on it. The parabolic trough is a type of solar thermal collector that is straight in one dimension and curved as a parabola in the other two, lined with a polished metal mirror. The rays of the sun that enter the mirror parallel to its plane of symmetry is focused along a focal line. Alternatively, a parabolic dish can also be used in place of the parabolic trough to obtain a focus point. Note however, that neither the focus point or the focal line are truly geometrically infinitesimal as the sun is not a point source of light, but rather an extended source of light.

The optics, cooling, photovoltaic cell, and the structural support (provided by the optical components of the photovoltaic system) are integrated in a single pipe like structure as shown in FIG. 2. The focus line is assumed to be in constant position and orientation with respect to a spectral absorber. The aligning of the focus line with respect to the parabolic trough can be performed by tracking. Specifically, a 1D tracking can be performed to ensure the alignment and the tracking can be performed either daily or seasonally.

The parabolic trough (or alternatively the parabolic dish) concentrates the light into a single focus point/line. The parabolic dish (trough) accepts energy from the sun (solar energy) and focuses the energy at the focus point/line, wherein an absorber is positioned in order to further convert into electrical energy.

Further, the solar light that is focused at the focal line is parallelized by a parallelizing element 202, such as refractive collimator or the like. A collimator is a device that narrows a light beam. Specifically, the collimator causes the directions of motion to become more aligned in a specific direction (i.e., collimated or parallel) or to cause the spatial cross section of the beam to become smaller. The concentrated light converges (i.e., focuses) at a line then diverges (i.e., defocuses) from that line in a parallel form. Both refractive and reflective collimators can be used to parallelize the beam.

However, according to one embodiment, refractive lenses are preferred. The lenses could be either of concave type for pre-focus placement or convex type for post-focus placement. The refractive/reflective lens is made of a material that has a refractive index such that chromatic dispersion is minimized. Further, the refractive element 202 parallelizes the light beam based on the curvature of the lens and not the thickness of the lens. Thus, the thickness of the lens can be minimized.

The parallelized collimated beam of light from the collimator 202 (represented as 202A) is incident on a reflective filter 203 that is disposed at a predetermined distance behind the collimator. Further, the reflective filter is oriented at an angle of inclination, for instance 45°, with respect to the collimator. The reflective filter may be a dichroic filter (for example a low pass, high pass, a band pass filter or the like) that is an accurate color filter used to selectively pass light of a small range of colors (wavelength/frequency of light) while reflecting other colors. The reflective filter 203 is configured to take as input the incident (parallel) beam of light from the collimator 202, and form a reflective portion of the incident spectrum 207 and an exit portion of the incident spectrum 209. Each of the reflective and exit portions of the incident spectrum (wavelengths of solar light) is incident on a photovoltaic cell 204a and 204b, respectively.

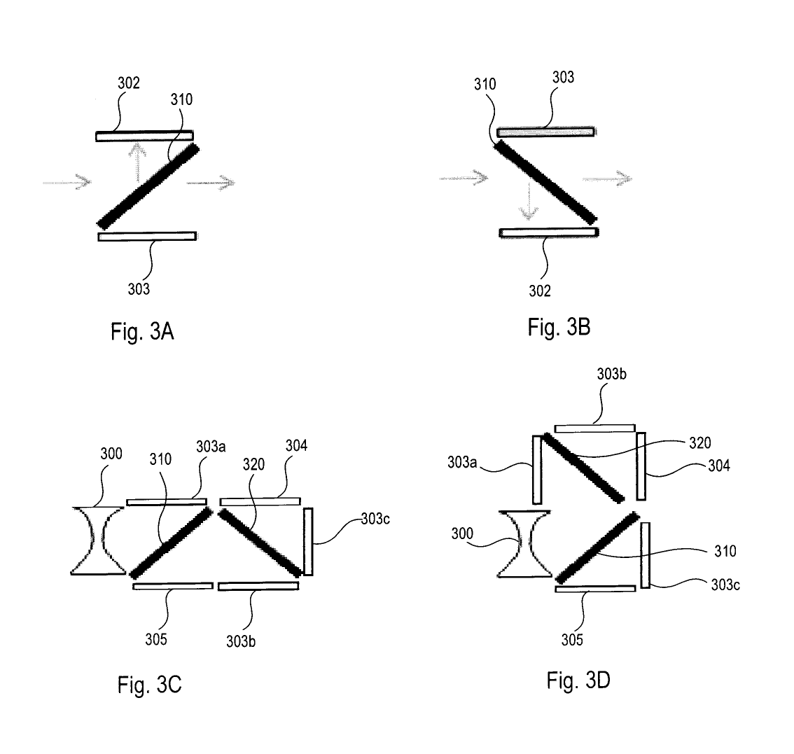

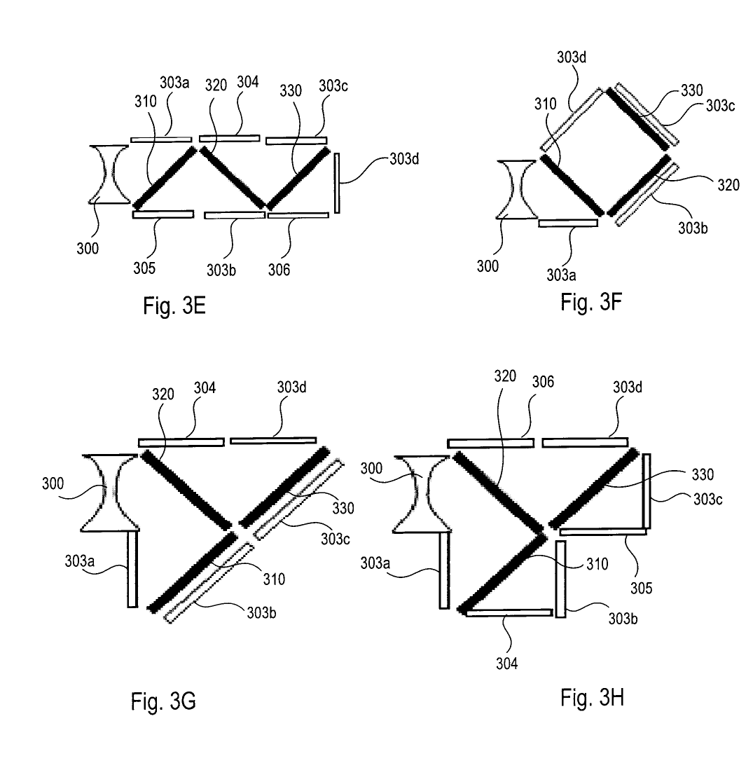

The photovoltaic cells 204a and 204b are single junction photovoltaic cells that convert solar energy into electrical energy. Furthermore, note that the system configuration is not limited to the configuration as represented in FIG. 2. For instance, a plurality of reflective mirrors and correspondingly a plurality of photovoltaic cells could be disposed on the rear side of the collimator, wherein each photovoltaic cell of the plurality of photovoltaic cells can be treated as an individual electrical element. Such configurations of the photovoltaic system are described with reference to FIGS. 3A-3H.

Furthermore, the photovoltaic system 200 also includes cooling elements 206a and 206b that are positioned behind the photovoltaic cells 204a and 204b respectively. The cooling unit is important from an operational prospective to keep the photovoltaic cells at a relatively low operational temperature, in order to improve the efficiency of the photovoltaic system and moreover preserve the lifetime of the cell.

The cooling can be achieved as either ‘active cooling’, which is performed by passing a cooling fluid into an enclosure. The cooling fluid could be surrounded by an insulating layer. Further, depending on the cooling temperature, the cooling flow can be configured so as to not gain heat from external atmosphere. According to another embodiment, the cooling can achieve by using a heat sink with passive radiators to cool the photovoltaic cells.

The photovoltaic system 200, may also include a protective enclosure (not shown in diagram for sake of clarity) to cover the optical elements and reflectors. That is, the protective enclosure could shield elements 202, 203, or the like from the environmental humidity and dust accumulation. A protective enclosure could also surround the optical element and serve as mechanical support, a heat radiator and the like.

FIGS. 3A-3H illustrate according to an embodiment, different configurations of the reflective filter(s) of the photovoltaic system.

The reflective filter in FIG. 2 can be disposed in a manner as shown in FIG. 3A, wherein the reflective filter 310 is disposed to form a ‘Z’ shape with respect to a photovoltaic cell 302 and a passive enclosing material 303. Further, the filter 310 can be disposed in manner as shown in FIG. 3B to form an ‘inverted Z’ shape with respect to a photovoltaic cell 302 and a passive enclosing material 303.

According to an embodiment, the photovoltaic system may include a plurality of reflective mirrors arranged in a cascaded manner as shown in FIG. 3C. Specifically, a reflective filter 310 may be followed by a second reflective filter 320. As stated previously, the reflective filter 310 takes as input, the collimated light from the collimator 300 and forms a reflective portion and an exit portion of the incident spectrum. The reflective portion of the spectrum is absorbed by the photovoltaic cell 303a, whereas the exit portion of the spectrum is incident on a second reflective filter 320. The reflective filter 320 takes as input the exit portion of the spectrum of the reflective filter 310, and further forms a reflective portion and an exit portion of its incident spectrum that are absorbed by photovoltaic cells 303b and 303c respectively. The reflective filters and the photovoltaic cells of FIG. 3C may be enclosed by a protective enclosing of 304 and 305 respectively, which shields the photovoltaic system from environmental humidity, dust pollution or the like.

The configuration of FIG. 3C can be modified such that the reflective portion of The incident spectrum (of the first reflective filter 310), is incident on the second reflective filter 320. Specifically, as shown in Fig, 3D, the second reflective filter 320 may be disposed above the first reflective filter 310 such that the reflective portion of the first filter 310 is incident on the second reflective filter 320.

The reflective filter 320 further divides the spectrum of light incident on it (i.e., the reflective portion of the first filter) into a reflective portion and an exit portion that are absorbed by photovoltaic cells 303a and 303b. The reflective filters and the photovoltaic cells of FIG. 3D may also be enclosed by a protective enclosing of 304 and 305 respectively, which shield the photovoltaic system from environmental humidity, dust pollution or the like.

According to another embodiment, a cascade of three reflective filters can be arranged as shown in FIG. 3E. In such a configuration, each of the reflective filters 320 and 330 are configured to split the exit portion of the spectrum of the previous filter. The cascade of filters may be arranged in a triangular waveform shape (i.e., a saw tooth shape) as shown in FIG. 3E. The reflective filter 320 splits the exit portion of the spectrum of filter 310, whereas the reflective filter 330 splits the exit portion of the spectrum of the filter 320. The corresponding reflective portions and exit portions of the reflective filters 310, 320 and 330 are absorbed by photovoltaic cells 303a-303d. Similar to the configurations of FIG. 3A-3D, the reflective filters and the photovoltaic cells of FIG. 3E may also be enclosed by a protective enclosing of 304 and 305 respectively, which shields the photovoltaic system from environmental humidity, dust pollution or the like.

Alternatively, according to another embodiment of the disclosure and as depicted in FIG. 3F, the reflective filters 310, 320 and 330 may be arranged in ‘a diamond’ shape with respect to photovoltaic cells 303a-303d. Specifically, the cascade of filters can be arranged in a ‘U’ shape manner. In such a configuration, the reflective filters 320 and 330 are configured to split one of a reflective portion and an exit portion of the spectrum of the previous reflective filter.

Further, according to another embodiment, the reflective filters may be arranged in such a manner such that both, the reflective portion and the exit portion of the spectrum, of the first reflective filter, is incident on the second and third filters respectively as shown in FIG. 3G. In this configuration, the cascade of filters can be arranges in a ‘T’ shape fashion. In FIG. 3G, the photovoltaic cells 303b and 303c are positioned (attached) directly behind the reflective filters 310 and 320. Alternatively, as shown in FIG. 3H, a predetermined amount of space may be provided between the reflective filters (310, 320) and the photovoltaic cells 303b and 303c, In providing such a space between the reflective filters and the photovoltaic cells, the total amount of photovoltaic material area is reduced.

For instance, comparing FIGS. 3G and 3H, the area of the area of the PV cell 303c used to absorb the exit spectrum from the filter 330 is wider in FIG. 3G than FIG. 3H. Thus, the configuration of FIG. 3H is preferred. Specifically, for a given amount of solar energy output from the filter 330, a wider photocell is used in FIG. 3G to capture the solar energy, thereby increasing the capture area and thereby the overall cost of the system. Thus, an embodiment of the present disclosure, provides the advantageous ability of reducing the capture area of the reflective filter by utilizing collimating optics. Thus, the present embodiment utilizes single junction photovoltaic cells that are more efficient from a cooling prospective as compared to multi-junction photovoltaic cells. Furthermore, while operating with single junction PV cells, a higher degree of freedom is achieved in the selection of PV materials and filters.

Note that in the embodiments described above, the number of photovoltaic cells in a given configuration is one greater than the number of reflecting filters. Furthermore, aspects of the present disclosure also provide for photovoltaic systems, wherein the number of reflective filters is not restricted to two or three filters. However, it must be appreciated that employing a higher number of cascaded filters will result in diminishing energy conversions, due to decreasing optical efficiency of higher number of optical elements.

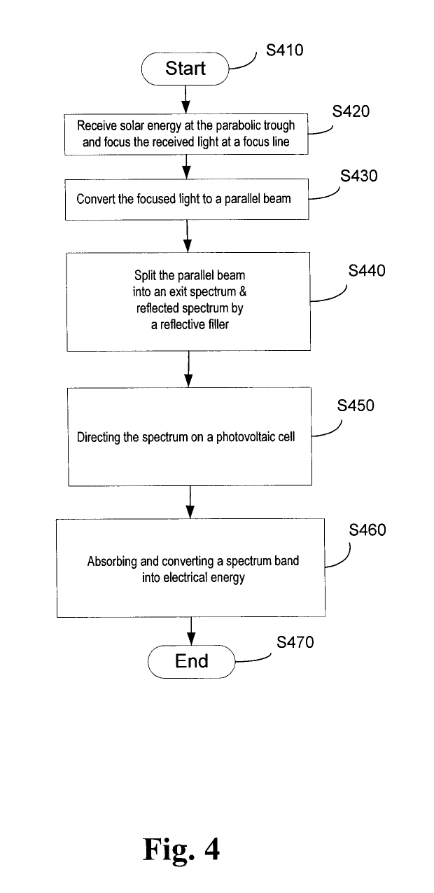

FIG. 4 depicts a flowchart illustrating the steps performed by the photovoltaic system.

The process starts in step S410 and proceeds to step S420. In step S420, solar energy is received by a parabolic trough (or dish) and the received light energy (i.e., solar light) is focused at a focus line/point of the parabolic trough (or dish).

In step S430, the focused light is converted into a parallel polychromatic light beam by a collimator. The parallelized light beam from the collimator is incident on a reflective filter. In step S440, the reflective filter splits the input spectrum in a reflective portion and an exit portion. The reflective portion of the spectrum is reflected off the surface of the reflective filter, whereas the exit portion of the spectrum passes through the reflective filter. Note that the reflective and exit portions of the spectrum include beams of certain wavelengths. Depending on the material of the reflective filter, certain wavelengths are reflected while the other wavelengths are passed through (i.e., exit) the filter.

The process then moves to step S450, wherein the reflective portion and the exit portion of the spectrum are incident on respective photovoltaic cells.

Further, in step S460, the respective photovoltaic cells convert the received light beams of the spectrum (reflective as well as exit spectrums) into electrical energy, where after the process simply ends in step S470.

Aspects of the present disclosure described above are in no way limited to the specific devices described therein. Variations of devices such as using a parabolic dish (2D concentration) can be used instead of a parabolic mirror. The parabolic dish has a reflective surface that is used to collect or project energy such as light, sound, or radio waves. The shape of the parabolic dish is of the form of a circular paraboloid, that is, the surface generated by a parabola revolving around its axis. Furthermore, the positioning and orientation of the optics such as the grating, collimator, and reflective filters can be controlled by a microcontroller, processor, a general purpose computer or the like. In what follows, a description is provided of a computing device that may be configured to control the operation of the optic devices described herein.

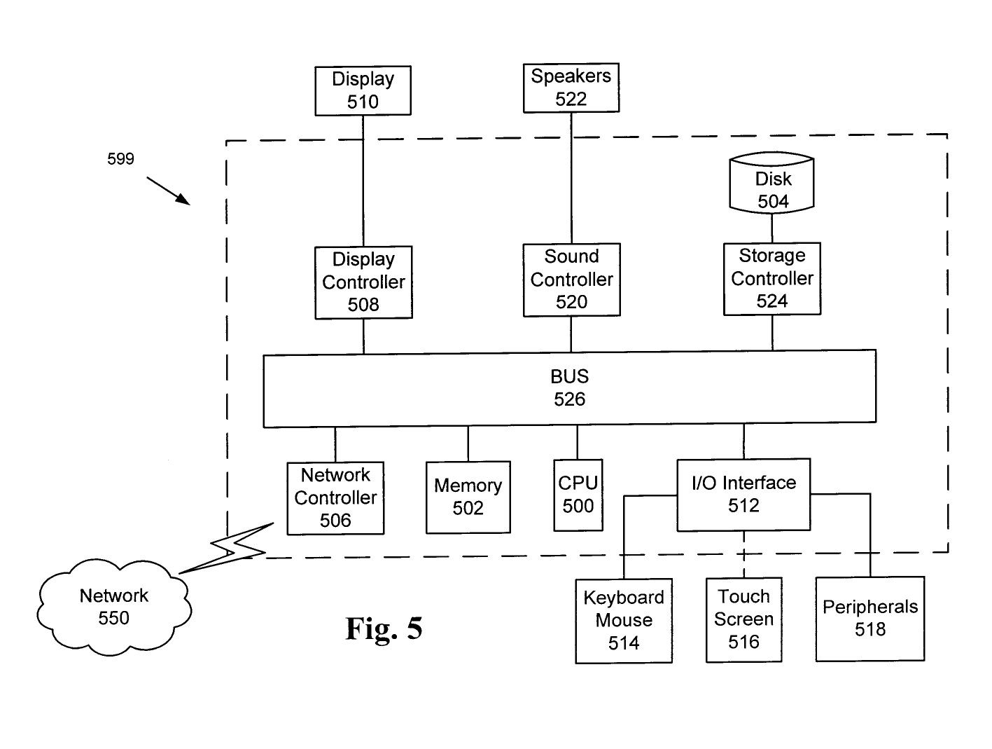

FIG. 5 illustrates a block diagram of a computing device according to an embodiment. In FIG. 5, the computer 599 includes a CPU 500 which performs the processes described above. The process data and instructions may be stored in memory 502. These processes and instructions may also be stored on a storage medium disk 304 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the system communicates, such as a server or computer.

Further, the claimed advancements may be provided as a utility application, background daemon, or component of an operating system, or combination thereof, executing in conjunction with CPU 500 and an operating system such as Microsoft Windows 7, UNIX, Solaris, LINUX, Apple MAC-OS and other systems known to those skilled in the art.

CPU 500 may be a Xenon or Core processor from Intel of America or an Opteron processor from AMD of America, or may be other processor types that would be recognized by one of ordinary skill in the art. Alternatively, the CPU 500 may be implemented on an FPGA, ASIC, PLD or using discrete logic circuits, as one of ordinary skill in the art would Recognize. Further, CPU 500 may be implemented as multiple processors cooperatively working in parallel to perform the instructions of the inventive processes described above.

The computer 599 in FIG. 5 also includes a network controller 506, such as an Intel Ethernet PRO network interface card from Intel Corporation of America, for interfacing with network 550. As can be appreciated, the network 550 can be a public network, such as the Internet, or a private network such as an LAN or WAN network, or any combination thereof and can also include PSTN or ISDN sub-networks. The network 550 can also be wired, such as an Ethernet network, or can be wireless such as a cellular network including EDGE, 3G and 4G wireless cellular systems. The wireless network can also be WiFi, Bluetooth, or any other wireless form of communication that is known.

The computer 599 further includes a display controller 508, such as a NVIDIA GeForce GTX or Quadro graphics adaptor from NVIDIA Corporation of America for interfacing with display 510, such as a Hewlett Packard HPL2445w LCD monitor, A general purpose I/O interface 512 interfaces with a keyboard and/or mouse 514 as well as a touch screen panel 516 on or separate from display 510. General purpose I/O interface also connects to a variety of peripherals 518 including printers and scanners, such as an OfficeJet or DeskJet from Hewlett Packard.

A sound controller 520 may also be provided in the computer 599, such as Sound Blaster X-Fi Titanium from Creative, to interface with speakers/microphone 522 thereby providing sounds and/or music.

The general purpose storage controller 524 connects the storage medium disk 304 with communication bus 526, which may be an ISA, EISA, VESA, PCI, or similar, for interconnecting all of the components of the robot-guided medical procedure system. A description of the general features and functionality of the display 510, keyboard and/or mouse 514, as well as the display controller 508, storage controller 524, network controller 506, sound controller 520, and general purpose I/O interface 512 is omitted herein for brevity as these features are known.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

1. A photovoltaic device comprising:
a concentrator configured to receive light and focus the received light at a focus point of the concentrator;
a collimator positioned at the focus point and configured to convert the focused light into a parallel beam of light;
a first reflective filter positioned at a predetermined distance behind the collimator and configured to receive and split the parallel beam of light into a first portion of light and a second portion of light;
a second reflective filter positioned at a predetermined angle with respect to the first reflective filter, and configured to receive and split the second portion of light into a third portion of light and a fourth portion of light;
a first single-junction photovoltaic cell configured to absorb the first portion of light and convert the absorbed light into electrical energy;
a second single-junction photovoltaic cell configured to absorb the third portion of light and convert the absorbed third portion into electrical energy; and
a third single junction photovoltaic cell configured to absorb the fourth portion of light and convert the absorbed fourth portion into electrical energy, wherein the second single-junction photovoltaic cell being disposed in a parallel fashion to the first single-junction photovoltaic cell, and being disposed in a perpendicular fashion to the third single-junction photovoltaic cell.

2. The photovoltaic device of claim 1, wherein the concentrator is one of a parabolic trough and a parabolic dish.

3. The photovoltaic device of claim 1, wherein a first direction of propagation of the first portion of light is perpendicular to a second direction of propagation of the second portion of light, and is parallel to a third direction of propagation of the third portion of light.

4. The photovoltaic device of claim 3, wherein the first single-junction photovoltaic cell is disposed perpendicular to the first direction of propagation of the first portion of light and the second single-junction photovoltaic cell is disposed perpendicular to the third direction of propagation of the third portion of light.

5. The photovoltaic device of claim 1, wherein the collimator is one of a concave refractive collimator and a convex refractive collimator.

6. The photovoltaic device of claim 1, wherein the second reflective filter is disposed behind the first reflective filter and forms an inverted ‘V’ shape.

7. The photovoltaic device of claim 1, further comprising:
a first cooler disposed directly behind the first single-junction photovoltaic cell, a second cooler disposed directly behind the second single-junction photovoltaic cell, and a third cooler disposed directly behind third single junction photovoltaic cell, the first cooler, the second cooler, and the third cooler being configured to maintain the first single-junction photovoltaic cell, the second single-junction photovoltaic cell, and the third single-junction photovoltaic cell at a predetermined operating temperature, respectively.

8. The photovoltaic device of claim 6, further comprising a third reflective filter disposed behind the second reflective filter, wherein the first reflective filter, the second reflective filter, and the third reflective filter form a saw-tooth shape.

9. The photovoltaic device of claim 1, further comprising:
a protective enclosure configured to shield at least the collimator and the respective reflective filters from environmental humidity and dust accumulation.

10. The photovoltaic device of claim 1, further comprising:
circuitry configured to align at least the collimator and the first reflective filter along a focal line of the concentrator.

11. A method of photovoltaic energy conversion, the method comprising:
receiving by a concentrator, light from a light source and focusing the received light at a focus point of the concentrator;
converting by a collimator positioned at the focus point, the focused light into a parallel beam of light;
receiving and splitting, by a first reflective filter positioned at a predetermined distance behind the collimator the parallel beam of light into a first portion of light and a second portion of light;
receiving and splitting, by a second reflective filter positioned at a predetermined angle with respect to the first reflective filter, the second portion of light into a third portion of light and a fourth portion of light;
absorbing by a first single-junction photovoltaic cell the first portion of light and converting the absorbed first portion of light into electrical energy;
absorbing by a second single junction photovoltaic cell the third portion of light and converting the absorbed third portion of light into electrical energy; and
absorbing by a third single-junction photovoltaic cell the fourth portion of light and converting the absorbed fourth portion of light into electrical energy; wherein the second single-junction photovoltaic cell is disposed in a parallel fashion to the first single-junction photovoltaic cell, and disposed in a perpendicular fashion to the third single-junction photovoltaic cell.

12. The method of claim 11, wherein the concentrator is one of a parabolic trough and a parabolic dish.

13. The method of claim 11, wherein a first direction of propagation of the first portion of light is perpendicular to a second direction of propagation of the second portion of light, and is parallel to a third direction of propagation of the third portion of light.

14. The method of claim 13, wherein the first single junction photovoltaic cell is disposed perpendicular to the first direction of propagation of the first portion of light and the second single junction photovoltaic cell is disposed perpendicular to the third direction of propagation of the third portion of light.

15. The method of claim 11, wherein the collimator is one of a concave refractive collimator and a convex refractive collimator.

16. The method of claim 11, wherein the second reflective filter is disposed behind the first reflective filter and forms an inverted ‘V’ shape.

17. The method of claim 11, further comprising:
cooling and maintaining, by a first cooler, a second cooler, and a third cooler, the first single-junction photovoltaic cell, the second single-junction photovoltaic cell, and the third single-junction photovoltaic cell at a predetermined operating temperature, respectively.

18. The method of claim 11, further comprising:
aligning by circuitry, at least the collimator and the first reflective filter along a focal line of the concentrator.

19. The method of claim 13, further comprising:
shielding by a protective enclosure, at least the collimator and the respective reflective filters from environmental humidity and dust accumulation.

20. A photovoltaic system comprising:
a concentrator configured to receive light and focus the received light at a focus point of the concentrator;
a collimator positioned at the focus point and configured to convert the focused light into a parallel beam of light;
a first reflective filter positioned at a predetermined distance behind the collimator and configured to receive and split the parallel beam of light into a first portion of light and a second portion of light;
a second reflective filter positioned at a predetermined angle with respect to the first reflective filter, and configured to receive and split the second portion of light into a third portion of light and a fourth portion of light;
a first single-junction photovoltaic cell configured to absorb the first portion of light and convert the absorbed light into electrical energy;
a second single-junction photovoltaic cell configured to absorb the third portion of light and convert the absorbed third portion into electrical energy;
a third single junction photovoltaic cell configured to absorb the fourth portion of light and convert the absorbed fourth portion into electrical energy, wherein the second single-junction photovoltaic cell being disposed in a parallel fashion to the first single-junction photovoltaic cell, and being disposed in a perpendicular fashion to the third single-junction photovoltaic cell; and
circuitry configured to align at least the collimator and the first reflective filter along a focal line of the concentrator
